(19) United States
(12) Patent Application Publication
(10) Pub. No.: US 2026/0239932 A1
(43) Pub. Date: Aug. 13, 2026

(54) PATTERN FORMING METHOD AND SEMICONDUCTOR MANUFACTURING APPARATUS

(71) Applicant: RAPIDUS CORPORATION, Tokyo (JP)

(72) Inventor: Tomonori Futai, Albany, NY (US)

(21) Appl. No.: 19/396,886

(22) Filed: Nov. 21, 2025

Related U.S. Application Data
(60) Provisional application No. 63/739,291, filed on Dec. 27, 2024.

(30) Foreign Application Priority Data
Oct. 21, 2025 (JP) 2025-177391

(51) Int. Cl. H10P 76/40; G03F 7/004; G03F 7/16

(52) U.S. Cl. CPC H10P 76/4085; G03F 7/0043; G03F 7/162; G03F 7/168

(57) ABSTRACT

In a pattern forming method according to the present embodiment, a MOR film is formed by applying a metal oxide resist containing moisture onto a processing target layer and heating the same, exposing the MOR film, heating the MOR film, developing the MOR film to form a resist pattern, and etching the processing target layer using the resist pattern as a mask to form a pattern.

### CROSS REFERENCE TO RELATED APPLICATIONS

This application claims priority to Japanese Patent Application No. JP 2025-177391 filed in the Japan Patent Office on Oct. 21, 2025, which claims the benefit of U.S. Provisional Application No. 63/739,291, filed Dec. 27, 2024.

### BACKGROUND OF THE INVENTION

### 1. Technical Field

The present embodiment relates to a pattern forming method and a semiconductor manufacturing apparatus.

### 2. Description of the Related Art

A metal oxide resist (MOR) has attracted attention as a next-generation resist that maximizes performance of next-generation extreme ultraviolet lithography (EUV) and contributes to further miniaturization and cost reduction. The metal oxide resist is a photoresist containing nanoparticles (metal oxide nanoparticles) of a metal oxide such as tin (Sn) having high EUV light absorption efficiency. The metal oxide resist has an advantage of having high sensitivity and high uniformity of a minimum line width (critical dimension (CD)) as compared with a currently mainstream chemical amplified resist (CAR).
JP2003139165A

### SUMMARY OF THE INVENTION

In contrast, in a case of metal oxide resist, the stability of a reaction mechanism is low with respect to moisture in the resist. Therefore, there is a possibility that pattern defects increase due to generation of resist residues (Scum) and the like in an unexposed portion.

An object to be solved by the present invention is to improve the shape and roughness of a pattern formed by etching using an etching mask formed using a metal oxide resist as a mask. Note that, the object is not limited to this, and an object corresponding to an effect obtained by a configuration of an embodiment to be described later may be an object of the present invention.

According to a pattern forming method according to the present embodiment, a MOR film is formed by applying a metal oxide resist containing moisture onto a processing target layer and heating the same,
exposing the MOR film,
heating the MOR film,
developing the MOR film to form a resist pattern, and
etching the processing target layer using the resist pattern as a mask to form a pattern.

A semiconductor manufacturing apparatus according to the present embodiment includes
a spin coating unit including a turntable that rotates a semiconductor substrate on which a processing target layer is formed,
a resist supply unit that supplies a metal oxide resist containing moisture onto the processing target layer, and
a heating unit that heats the semiconductor substrate on which the metal oxide resist containing moisture is applied onto the processing target layer, in which
the resist supply unit includes
a nozzle that discharges the metal oxide resist containing moisture,
a MOR supply line connected to the nozzle and through which the metal oxide resist circulates, and
a water addition line connected to the nozzle or the MOR supply line through which water circulates.

### BRIEF DESCRIPTION OF THE DRAWINGS

FIG. 1 is a flowchart for explaining a pattern forming method according to an embodiment;

FIG. 2A is a schematic cross-sectional view for explaining the pattern forming method according to the embodiment;

FIG. 2B is a schematic cross-sectional view for explaining the pattern forming method according to the embodiment subsequent to FIG. 2A;

FIG. 2C is a schematic cross-sectional view for explaining the pattern forming method according to the embodiment subsequent to FIG. 2B;

FIG. 2D is a schematic cross-sectional view for explaining the pattern forming method according to the embodiment subsequent to FIG. 2C;

FIG. 2E is a schematic cross-sectional view for explaining the pattern forming method according to the embodiment subsequent to FIG. 2D;

FIG. 2F is a schematic cross-sectional view for explaining the pattern forming method according to the embodiment subsequent to FIG. 2E;

FIG. 3A is a schematic cross-sectional view for explaining a pattern forming method according to a comparative example corresponding to FIG. 2B;

FIG. 3B is a schematic cross-sectional view for explaining the pattern forming method according to the comparative example subsequent to FIG. 3A;

FIG. 3C is a schematic cross-sectional view for explaining the pattern forming method according to the comparative example subsequent to FIG. 3B;

FIG. 3D is a schematic cross-sectional view for explaining the pattern forming method according to the comparative example subsequent to FIG. 3C; and

FIG. 4 is a plane view illustrating a schematic configuration of a semiconductor manufacturing apparatus according to the embodiment.

### DETAILED DESCRIPTION

Hereinafter, an embodiment according to the present invention will be described with reference to the drawings. The present embodiment does not limit the present invention. The drawings are schematic or conceptual. In the specification and the drawings, the same elements are denoted by the same reference numerals.

### <Pattern Forming Method>

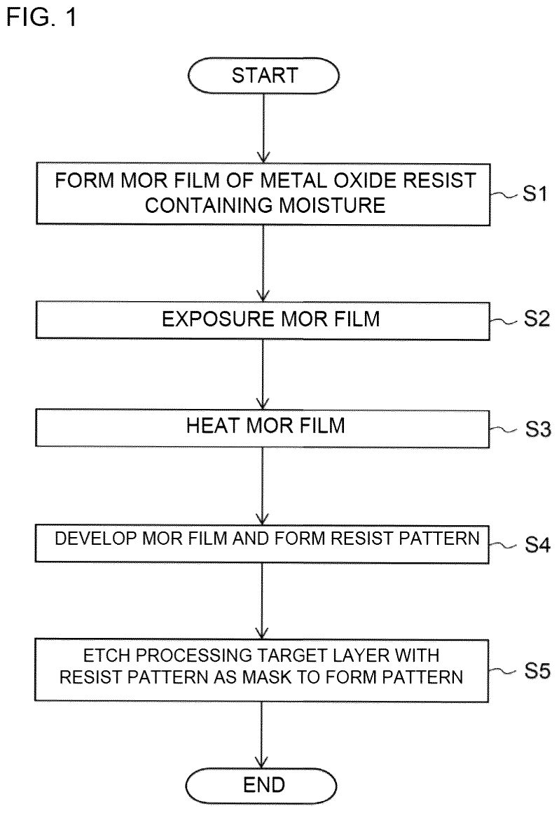

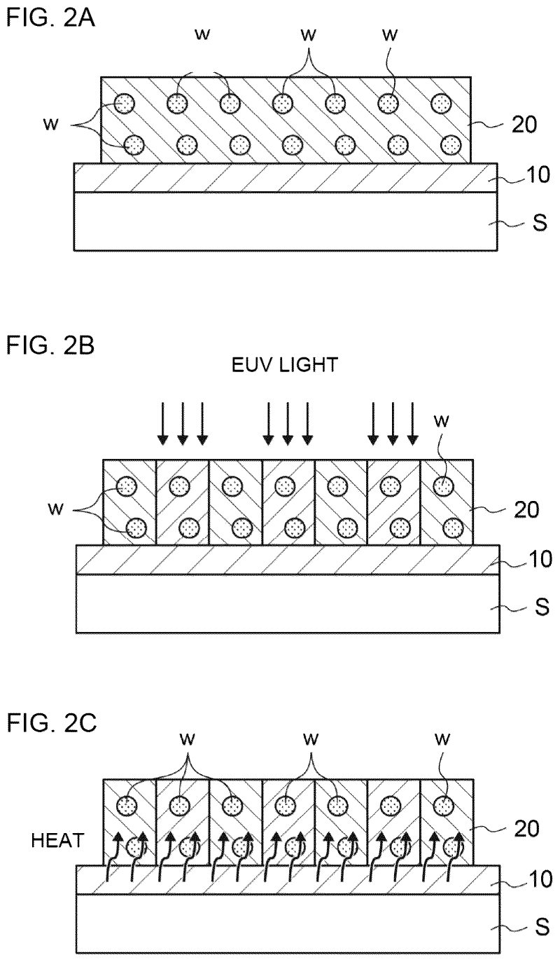

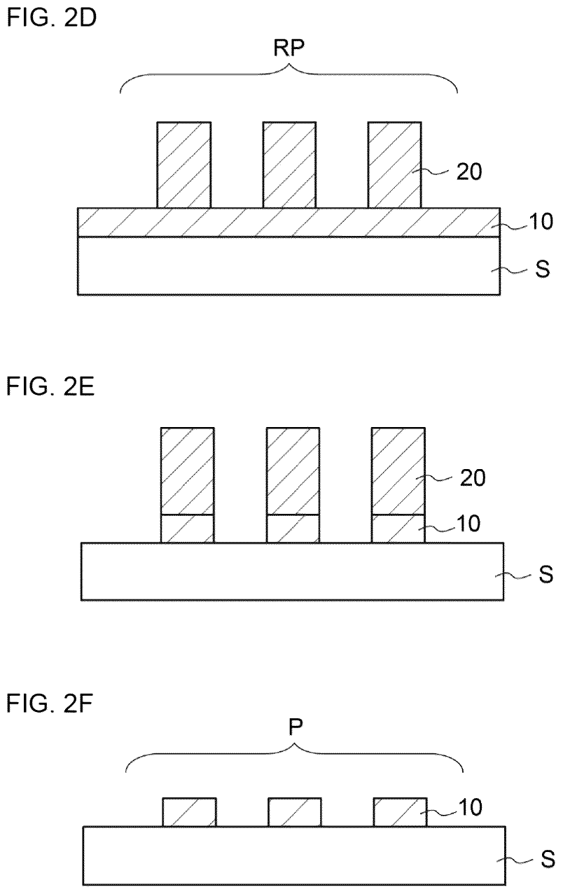

A pattern forming method according to the embodiment will be described with reference to a flowchart of FIG. 1 and FIGS. 2A to 2F. The pattern forming method according to the present embodiment is applicable to manufacturing of a semiconductor device such as a memory device or a logic device.

Step S1: A MOR film 20 is formed of a metal oxide resist containing moisture w. In the present embodiment, the moisture w is pure or ultrapure water.

Specifically, as illustrated in FIG. 2A, a metal oxide resist (MOR) is applied onto a processing target layer 10 formed on a semiconductor substrate S by spin coating or the like, and heated by a hot plate or the like to form the MOR film 20. As illustrated in FIG. 2A, the MOR film 20 contains the moisture w. The metal oxide resist to be applied contains, for example, 0.001 wt % to 20 wt % of moisture, preferably 1 wt % to 10 wt % of moisture, and more preferably 3 wt % to 7 wt % of moisture.

When applying the metal oxide resist, the metal oxide resist is dropped or the like from a nozzle to be supplied onto the processing target layer 10, and the semiconductor substrate S is rotated at a high speed. The applied metal oxide resist is heated (pre-baked) at temperature and for a time with which moisture in the metal oxide resist does not disappear (for example, 200° C. to 250° C. and about 30 seconds to 90 seconds). As a result, at least a part of solvent of the metal oxide resist is evaporated, and the film is stabilized.

Note that, metal atoms of metal oxide nanoparticles (not illustrated) contained in the metal oxide resist are Sn (tin) in the present embodiment, but may be other metal atoms such as Zr (zirconium), Hf (hafnium), Ti (titanium), Zn (zinc), and Al (aluminum).

The semiconductor substrate S is, for example, a silicon wafer, but may be a semiconductor wafer made of another semiconductor material (silicon carbide, compound semiconductor and the like). Note that, the semiconductor substrate S is not limited to the semiconductor wafer, and may be an epitaxial layer, or may be a semiconductor wafer and an epitaxial layer formed thereon.

A type of the processing target layer 10 is not particularly limited, and may be a semiconductor layer (for example, an n-type or p-type silicon layer), a conductive layer (for example, a polysilicon layer or a metal layer), or an insulating layer (for example, a SiO₂ film, a Si₃N₄ film, and a SiOC film).

Step S2: The MOR film 20 formed at step S2 is exposed. Specifically, as illustrated in FIG. 2B, the MOR film 20 is exposed by extreme ultraviolet lithography (EUV lithography). In an exposed portion of the MOR film 20, metal atoms are desorbed from an organic ligand, and metal atom radicals (M·) are generated.

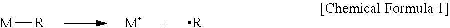

Here, M is a metal atom, and R is an organic ligand.

A part of the metal atom radicals generated in this manner reacts with the moisture w (H₂O) in the MOR film 20, thereby generating metal hydroxyl groups (M-OH).

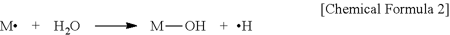

In the present embodiment, since the MOR film 20 is formed using the metal oxide resist containing moisture, the moisture concentration of the MOR film 20 is substantially uniform in a film thickness direction at a time point before next step S3 is performed.

Step S3: The MOR film 20 exposed at step S2 is heated. This step is a post-bake (PEB) step. Specifically, as illustrated in FIG. 2C, the semiconductor substrate S is placed on a hot plate and heated. Heating conditions are, for example, 90° C. to 120° C. and about 30 seconds to 90 seconds.

When the MOR film 20 is heated, a condensation reaction (the following formula) occurs in an exposed region, and an insoluble substance (M-O-M) is formed.

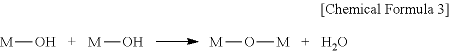

Step S4: The MOR film 20 heated at step S3 is developed to form a resist pattern RP. Specifically, as illustrated in FIG. 2D, a portion exposed at step S2 out of the MOR film 20 remains and the resist pattern RP is formed.

Step S5: The processing target layer 10 is etched using the resist pattern RP formed at step S4 as a mask to form a pattern P. That is, as illustrated in FIG. 2E, the processing target layer 10 is etched using the resist pattern RP as an etching mask, and then the resist pattern RP is removed. As a result, a desired pattern P illustrated in FIG. 2F is formed.

As described above, according to the pattern forming method according to the present embodiment, the MOR film 20 containing moisture is formed on the processing target layer 10, the MOR film 20 is exposed, heated, and developed to form the resist pattern RP, and the processing target layer 10 is etched using the resist pattern RP as the mask to form the pattern P. As a result, the shape and roughness of the pattern P can be improved.

The above-described effect will be described in further detail through the description of a comparative example.

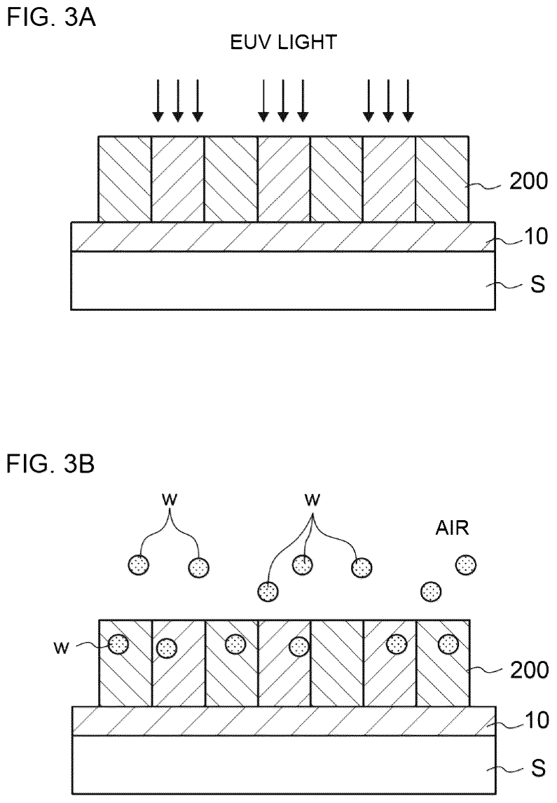

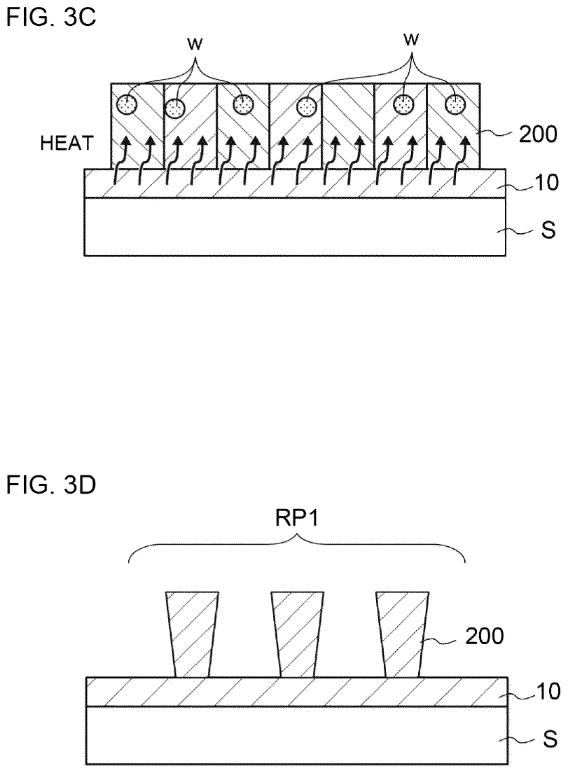

FIG. 3A is a schematic cross-sectional view of a MOR film 200 according to the comparative example at an exposure step. Since the MOR film 200 does not contain moisture, the reaction of Chemical Formula 2 described above does not occur. Before the post-bake step (for example, during a PED step to be described later), the moisture w in the air is absorbed by the MOR film 200 as illustrated in FIG. 3B, so that M-OH is generated. However, moisture absorbed by the MOR film 200 from the air is not uniform, and moisture content density is high near an upper portion of the MOR film 200. Therefore, a large amount of M-OH is present in the upper portion of the MOR film 200. In contrast, since the density of M-OH is low in a lower portion of the MOR film 200, a reaction of Chemical Formula 3 hardly occurs. Therefore, at the post-bake step illustrated in FIG. 3C, insoluble M-O-M is formed around the upper portion of the MOR film 200.

Therefore, when the MOR film 200 after the post-bake step is developed, as illustrated in FIG. 3D, although the upper portion out of an exposed region of the MOR film 200 remains, the residual ratio decreases toward the lower portion, and a cross section of the resist pattern RP is reversely tapered. Therefore, a pattern formed by etching the processing target layer 10 using a resist pattern RP1 as a mask deteriorates in shape and roughness.

In contrast, in the present embodiment, since moisture is contained in advance in the metal oxide resist supplied onto the processing target layer 10, the moisture in the air is absorbed around the upper portion of the metal oxide resist after the metal oxide resist is supplied onto the processing target layer 10, so that a large change in the moisture concentration in the film thickness direction is suppressed. In this manner, according to the present embodiment, by forming the MOR film 20 by applying and heating the metal oxide resist containing moisture, the moisture concentration of the MOR film 20 becomes substantially uniform in the film thickness direction at a time point before the post-bake step is performed. Therefore, at the post-bake step, the reaction of Chemical Formula 3 occurs substantially uniformly in the film thickness direction of the MOR film 200, and insoluble M-O-M is generated. Therefore, the cross section of the resist pattern RP is not reversely tapered as illustrated in FIG. 2D, and as a result, the pattern P having a desired shape and excellent roughness performance can be formed.

Note that, step S3 (heating of the MOR film 20) may be performed after a lapse of a predetermined time (for example, about several minutes) from the exposure of the MOR film 20 at step S2. That is, a post-exposure delay (PED) step may be included between the exposure step and the pre-bake step.

In a case where the PED step is performed, the moisture content of the metal oxide resist may be gradually reduced while the metal oxide resist containing the moisture w is supplied onto the processing target layer 10 at step S1. In this manner, the amount of moisture in the lower portion (the side close to the semiconductor substrate S) of the resist film applied onto the processing target layer 10 increases, and the amount of moisture decreases toward the upper portion of the resist film. As a result of the moisture in the air being absorbed from the upper portion of the MOR film 20 at the PED step, the uniformity of the moisture concentration in the film thickness direction of the MOR film 20 can be enhanced at the time point before the post-bake step is performed.

In a case where the PED step is performed, the rotational speed (rpm) of the semiconductor substrate S on which the processing target layer 10 is formed may be gradually increased while the metal oxide resist containing the moisture w is supplied onto the processing target layer 10 at step S1. Since the metal oxide resist and moisture differ in ease of scattering from the semiconductor substrate S rotating at a high speed due to a difference in viscosity, by doing in the above-described manner, the amount of moisture in the lower portion (side close to the semiconductor substrate S) of the resist film applied onto the processing target layer 10 increases and the amount of moisture decreases toward the upper portion of the resist film. As a result of the moisture in the air being absorbed from the upper portion of the MOR film 20 at the PED step, the uniformity of the moisture concentration in the film thickness direction of the MOR film 20 can be enhanced at the time point before the post-bake step is performed.

### <Semiconductor Manufacturing Apparatus>

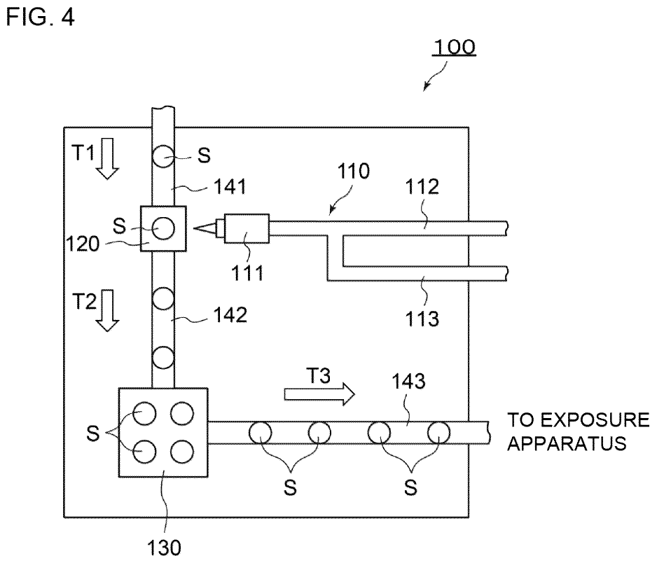

A semiconductor manufacturing apparatus 100 according to an embodiment will be described with reference to FIG. 4. The semiconductor manufacturing apparatus 100 is configured to receive the semiconductor substrate S (semiconductor wafer) from outside, apply the metal oxide resist containing moisture onto the processing target layer 10 of the semiconductor substrate S, and heat the same to form the MOR film 20.

The semiconductor manufacturing apparatus 100 includes a resist supply unit 110, a spin coating unit 120, a heating unit 130, and conveyance units 141, 142, and 143. Although not illustrated, the semiconductor manufacturing apparatus 100 may include a pickup mechanism of the semiconductor substrate S or a mechanism for aligning the semiconductor substrates S.

The resist supply unit 110 is configured to supply the metal oxide resist containing moisture onto the processing target layer 10 formed on the semiconductor substrate S. In the present embodiment, the resist supply unit 110 drops the metal oxide resist toward the semiconductor substrate S fixed to a turntable of the spin coating unit 120.

The resist supply unit 110 includes a nozzle 111 that discharges the metal oxide resist containing moisture, a MOR supply line 112 that is connected to the nozzle 111 and through which the metal oxide resist circulates, and a water addition line 113 through which water circulates. The metal oxide resist that circulates through the MOR supply line 112 does not contain moisture. However, it is not necessarily that this does not contain moisture at all, and this may contain very little (for example, 0.0001 wt % or less) moisture.

Note that, the water addition line 113 may be connected to the MOR supply line 112 as illustrated in FIG. 4, or may be connected to the nozzle 111. In the latter case, the metal oxide resist and water are mixed inside the nozzle 111. By such resist supply unit 110, a mixture of water and the metal oxide resist is discharged from the nozzle 111 and applied onto the processing target layer 10.

As described above, in the resist supply unit 110, since the water addition line 113 is connected to the nozzle 111 or the MOR supply line 112, the metal oxide resist and water are mixed immediately before being discharged from the nozzle 111 and supplied onto the processing target layer 10. This makes it possible to manage the moisture content of the metal oxide resist to a desired concentration with a simple configuration. By mixing water of a predetermined concentration with the metal oxide resist discharged from the nozzle 111 in this manner, even if moisture in the air is about to enter the metal oxide resist on the processing target layer 10, the moisture concentration is suppressed from changing to a predetermined concentration or more due to so-called gas-liquid equilibrium, and the moisture concentration in the metal oxide resist is maintained.

Note that, in order to control the amount of moisture contained in the metal oxide resist discharged from the nozzle 111, a valve (not illustrated) such as a needle valve or a simple proportional valve may be provided before a portion where the water addition line 113 joins the MOR supply line 112. A mass flowmeter may be provided in the MOR supply line 112 and/or the water addition line 113, and the flow rate of the MOR supply line 112 and/or the water addition line 113 may be measured to control the valve.

The moisture content of the metal oxide resist in the nozzle 111 is monitored, and in a case where the moisture content deviates from a target value, the flow rate of the MOR supply line 112 and/or the water addition line 113 may be adjusted. For the measurement of the moisture content, a refractive index sensor, a viscosity sensor, a near-infrared spectroscopic sensor, or the like can be used.

The nozzle 111 may include a valve (for example, a solenoid valve or a pinch valve) at a distal end in order to control the discharge amount (supply amount) of the metal oxide resist containing moisture.

The spin coating unit 120 includes a turntable that rotates the semiconductor substrate S. The spin coating unit 120 rotates at a high speed the semiconductor substrate S conveyed by the conveyance unit 141 and fixed to the turntable. The metal oxide resist containing moisture is supplied (dropped) from the resist supply unit 110 in a state in which the semiconductor substrate S rotates at a high speed, so that a resist film is formed on the processing target layer 10.

Note that, the resist supply unit 110 may gradually decrease the moisture content of the metal oxide resist while the metal oxide resist containing moisture is supplied (discharged) onto the processing target layer 10. For example, an opening degree of the valve provided in the water addition line 113 is gradually reduced. By discharging the metal oxide resist containing a relatively large amount of moisture at an initial stage of discharge and gradually decreasing the moisture content, the amount of moisture in the lower portion (side close to the semiconductor substrate S) of the resist film applied onto the processing target layer 10 increases and the amount of moisture decreases toward the upper portion of the resist film. Therefore, as a result of the moisture in the air being absorbed from the upper portion of the MOR film 20 at the PED step, the uniformity of the moisture concentration in the film thickness direction of the MOR film 20 at the time point before the post-bake step can be enhanced.

While supplying (discharging) the metal oxide resist containing moisture onto the processing target layer 10, the resist supply unit 110 may gradually increase the rotational speed (rpm) of the semiconductor substrate S on which the processing target layer 10 is formed. Since moisture scatters more easily than the metal oxide resist on the semiconductor substrate S rotating at a high speed, by doing so, the amount of moisture in the lower portion (side close to the semiconductor substrate S) of the resist film applied onto the processing target layer 10 increases and the amount of moisture decreases toward the upper portion of the resist film. As a result of the moisture in the air being absorbed from the upper portion of the MOR film 20 at the PED step, the uniformity of the moisture concentration in the film thickness direction of the MOR film 20 at the time point before the post-bake step can be enhanced.

As described above, a moisture profile at a discharge stage of the resist may be set in anticipation of moisture absorption at the PED step so that the moisture content of the metal oxide resist is as uniform as possible in the film thickness direction before the post-bake step. This is effective in enhancing the uniformity of the moisture concentration in the film thickness direction of the MOR film 20 before the post-bake step.

The heating unit 130 is configured to heat the semiconductor substrate S conveyed by the conveyance unit 142 on which the metal oxide resist containing moisture is applied onto the processing target layer 10. In the present embodiment, the heating unit 130 includes a hot plate, and the semiconductor substrate S is placed on the hot plate. A heating unit of the hot plate is, for example, a ceramic heater, a resistance wire embedded heater, a mica heater, or the like. Heating conditions are, for example, 200° C. to 250° C. and about 30 seconds to 90 seconds. Note that, as illustrated in FIG. 4, a plurality of semiconductor substrates S may be placed on the hot plate and heated at once.

The conveyance units 141, 142, and 143 convey the semiconductor substrate S. The conveyance unit 141 conveys the semiconductor substrate S received from outside of the semiconductor manufacturing apparatus 100 to the spin coating unit 120 in a conveyance direction T1. The conveyance unit 142 conveys the semiconductor substrate S from the spin coating unit 120 to the heating unit 130 in a conveyance direction T2. The conveyance unit 143 conveys the semiconductor substrate S from the heating unit 130 to the outside of the semiconductor manufacturing apparatus 100 (for example, an exposure apparatus) in a conveyance direction T3. Note that, the conveyance units 141, 142, and 143 are not limited to one conveyance line, and may include a plurality of conveyance lines.

According to the semiconductor manufacturing apparatus 100 according to the present embodiment, the semiconductor substrate S received from the outside of the apparatus is conveyed to the spin coating unit 120 by the conveyance unit 141, and the resist supply unit 110 applies the metal oxide resist containing moisture on the processing target layer 10 of the semiconductor substrate S fixed to the turntable of the spin coating unit 120. The heating unit 130 then heats the applied metal oxide resist to evaporate the solvent, thereby forming the MOR film 20.

The semiconductor substrate S unloaded from the semiconductor manufacturing apparatus 100 is thereafter conveyed to an exposure apparatus such as an EUV lithography apparatus not illustrated or a development apparatus, and the MOR film 20 is exposed and developed to form the resist pattern RP. Thereafter, in an etching apparatus not illustrated, the processing target layer 10 is etched using the resist pattern RP as the mask to form the resist pattern RP having a desired shape and excellent roughness performance. By etching the processing target layer 10 using the resist pattern RP as the etching mask, an excellent pattern P can be formed.

Note that, the semiconductor manufacturing apparatus 100 of the present embodiment is configured as a so-called coater apparatus, but the configuration of the semiconductor manufacturing apparatus 100 is not limited to the above. For example, the semiconductor manufacturing apparatus 100 may include an exposure unit and a development unit that receive the semiconductor substrate S heated by the heating unit 130 and pattern the MOR film 20, and may further include an etching unit that etches the processing target layer 10 using the patterned MOR film 20 as a mask.

On the basis of the above description, a person skilled in the art may conceive additional effects and various modifications of the present invention, but aspects of the present invention are not limited to the individual embodiments described above. Components in different embodiments may be appropriately combined. Various additions, modifications, and partial deletions can be made without departing from the conceptual idea and spirit of the present invention derived from the contents defined in claims and equivalents thereof.
10 processing target layer
20, 200 MOR film
100 semiconductor manufacturing apparatus
110 resist supply unit
111 nozzle
112 MOR supply line
113 water addition line
120 spin coating unit
130 heating unit
141, 142, 143 conveyance units
RP, RP1 resist pattern
P pattern
S semiconductor substrate
T1, T2, T3 conveyance direction
w moisture

What is claimed is:

1. A pattern forming method comprising:
forming a MOR film by applying a metal oxide resist containing moisture onto a processing target layer and heating the metal oxide resist;
exposing the MOR film;
heating the MOR film;
developing the MOR film to form a resist pattern; and
etching the processing target layer using the resist pattern as a mask to form a pattern.

2. The pattern forming method according to claim 1, wherein the moisture is pure or ultrapure water.

3. The pattern forming method according to claim 1, wherein the metal oxide resist contains 3 wt % to 7 wt % of moisture.

4. The pattern forming method according to claim 1, wherein the MOR film is heated after a predetermined time elapses from exposure of the MOR film.

5. The pattern forming method according to claim 4, wherein a moisture content of the metal oxide resist is gradually decreased while the metal oxide resist containing moisture is supplied onto the processing target layer.

6. The pattern forming method according to claim 4, wherein a rotational speed of a semiconductor wafer on which the processing target layer is formed is gradually increased while the metal oxide resist containing moisture is supplied onto the processing target layer.

7. The pattern forming method according to claim 1, wherein moisture concentration of the MOR film is substantially uniform in a film thickness direction at a time point before the MOR film is heated.

8. A semiconductor manufacturing apparatus comprising:
a spin coating unit including a turntable that rotates a semiconductor substrate on which a processing target layer is formed;
a resist supply unit that supplies a metal oxide resist containing moisture onto the processing target layer; and
a heating unit that heats the semiconductor substrate on which the metal oxide resist containing moisture is applied onto the processing target layer, wherein
the resist supply unit includes:
a nozzle that discharges the metal oxide resist containing moisture;
a MOR supply line connected to the nozzle and through which the metal oxide resist circulates; and
a water addition line connected to the nozzle or the MOR supply line through which water circulates.

9. The semiconductor manufacturing apparatus according to claim 8, wherein the resist supply unit gradually decreases a moisture content of the metal oxide resist while supplying the metal oxide resist containing moisture onto the processing target layer.

10. The semiconductor manufacturing apparatus according to claim 8, wherein the resist supply unit gradually increases a rotational speed of a semiconductor wafer on which the processing target layer is formed while the metal oxide resist containing moisture is supplied onto the processing target layer.
